(19) United States
(12) Patent Application Publication
(10) Pub. No.: US 2026/0068596 A1
(43) Pub. Date: Mar. 5, 2026

(54) SEMICONDUCTOR DEVICE AND METHOD OF MANUFACTURING THE SAME

(71) Applicant: VisEra Technologies Company Ltd., Hsin-Chi City (TW)

(72) Inventors: Jhih-Jian HE, Hsin-Chu City (TW); Tsung-Ming CHEN, Hsin-Chu City (TW); Ming-Lun SHIH, Hsin-Chu City (TW); Ming-Yi SHEN, Hsin-Chu City (TW)

(21) Appl. No.: 19/055,808

(22) Filed: Feb. 18, 2025

Related U.S. Application Data
(60) Provisional application No. 63/687,506, filed on Aug. 27, 2024.

(51) Int. Cl. H01L 21/687

(52) U.S. Cl. CPC H01L 21/68721

(57) ABSTRACT

According to an aspect of the disclosure, a substrate holder includes a first retaining ring, a second retaining ring, a mounting component configured to detachably mount the first retaining ring on the second retaining ring; and a plurality of pins disposed on an inner circumference of each of the first and second retaining rings. Each of the pins has a curved surface at a distal end of each of the pins.

### CROSS REFERENCE TO RELATED APPLICATIONS

This application claims priority of U.S. Provisional Application No. 63/687,506 filed on Aug. 27, 2024 under 35 U.S. C. § 119(e), the entire contents of all of which are hereby incorporated by reference.

### BACKGROUND

### Field of Invention

The present disclosure relates to a semiconductor device and a method of manufacturing the same.

### Description of Related Art

Integrated chips are formed by complex fabrication processes, during which a workpiece is subjected to different steps to form one or more semiconductor devices. Some of the processing steps may include forming a thin film onto a substrate. Thin films can be deposited onto the substrate in a low-pressure processing chamber using physical vapor deposition.

With the development of semiconductor industry, the thickness of the substrate is getting thinner and thinner. Therefore, there is a need to solve the cracking issue of the substrate with an ultra-thin thickness.

### SUMMARY

It is to be understood that both the foregoing general description and the following detailed description are by examples, and are intended to provide further explanation of the disclosure as claimed.

According to an aspect of the disclosure, a substrate holder includes a first retaining ring, a second retaining ring, a mounting component configured to detachably mount the first retaining ring on the second retaining ring; and a plurality of pins disposed on an inner circumference of each of the first and second retaining rings. Each of the pins has a curved surface at a distal end of each of the pins.

In some embodiments, each of the pins includes a support piece and a cushion disposed on the support piece, and the cushion of each of the pins has the curved surface.

In some embodiments, a thickness of the cushion of each of the pins is in a range from 0.5 mm to 1 mm.

In some embodiments, the curved surface of each of the pins is a curved corner at the distal end of each of the pins.

In some embodiments, the curved surface of each of the pins is a curved side surface that interconnects a top surface and a bottom surface of each of the pins.

In some embodiments, the curved surface is spaced from a substrate when the substrate is clamped in the substrate holder.

In some embodiments, a contact surface of each of the pins against a substrate is a planar surface.

In some embodiments, a surface roughness of each of the pins is in a range from 50 μm to 300 μm.

In some embodiments, the mounting component including a first group of magnets embedded in the first retaining ring and a second group of magnets embedded in the second retaining ring, and the first group of magnets and the second group of magnets have opposite poles facing each other.

In some embodiments, a number of the first group of magnets embedded in the first retaining ring is equal to a number of the pins of the first retaining ring.

In some embodiments, the pins are C-shaped distributed or O-shaped distributed on the inner circumference of each of the first and second retaining rings.

In some embodiments, the substrate holder further includes two rotary shafts connecting the first retaining ring, wherein the rotary shafts are extended along a rotating axis.

In some embodiments, the pins include a first pin and a second pin that is disposed closer to the rotating axis than the first pin, and a circumference dimension of the first pin is greater than a circumference dimension of the second pin.

In some embodiments, the pins are symmetrically arranged along the rotating axis.

In some embodiments, the substrate holder further includes a support frame connected to the second retaining ring by the rotary shafts, wherein the second retaining ring and the rotary shafts are flippable relative to the support frame.

In some embodiments, the support frame is configured to couple to a rotation holder of a rotation apparatus.

In some embodiments, the substrate holder includes two position mechanisms configured to couple the rotary shafts to the support frame, respectively.

In some embodiments, each of the pins has a thickness in a range from 0.1 mm to 20 mm.

In some embodiments, each of the pins has a circumference dimension in a range from 1 cm to 2 πR cm, in which R is a radius of the first retaining ring.

In some embodiments, each of the pins has a radius dimension in a range from 0.1 mm to 30 mm.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is an oblique view of a substrate holder according to some embodiments of the disclosure.

FIG. 2 is a schematic cross-sectional view of the substrate holder with the substrate according to some embodiments of the disclosure.

FIG. 3 is a schematic cross-sectional view of the substrate holder with the substrate according to some other embodiments of the disclosure.

FIG. 4 is partial oblique view of the substrate according to some embodiments of the disclosure.

FIG. 5 is a schematic top view of the arrangement of the pins according to some embodiments of the disclosure.

FIG. 6 is a schematic top view of the arrangement of the pins according to some other embodiments of the disclosure.

FIG. 7 is an oblique view of the substrate holder according to some embodiments of the disclosure.

FIG. 8 is a schematic top view of region A of the substrate holder of FIG. 7.

FIG. 9 is a flow of a method of coating a substrate using the substrate holder according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

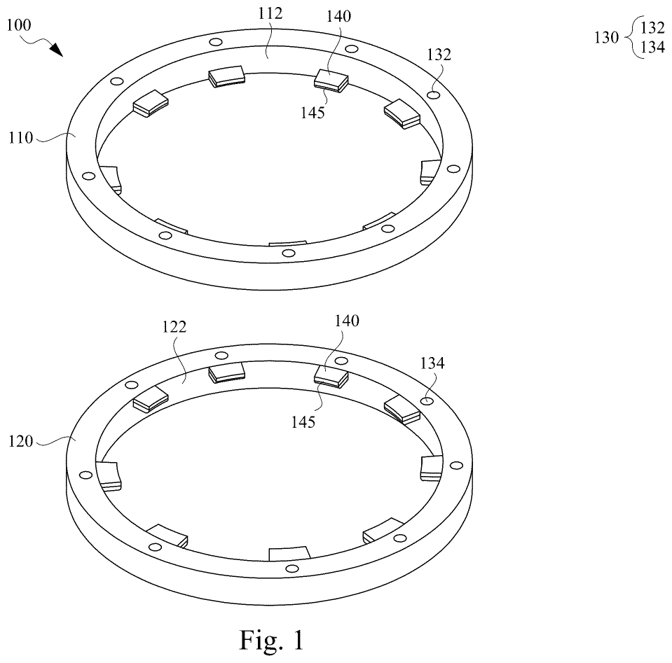

Reference is made to FIG. 1, which is an oblique view of a substrate holder according to some embodiments of the disclosure. The substrate holder 100 includes a first retaining ring 110, a second retaining ring 120, and a mounting component 130 that is configured to detachably mount the first retaining ring 110 on the second retaining ring 120. The substrate holder 100 further includes a plurality of pins 140 disposed on inner circumferences 112, 122 of the first and second retaining rings 110, 120. Each of the pins 140 is laterally extended from the inner circumferences 112, 122 of the first and second retaining rings 110, 120, and a distal end 145 of each of the pins 140 points toward the center of the first and second retaining rings 110, 120.

In some embodiments, the mounting component 130 includes a first group of magnets 132 embedded in the first retaining ring 110 and a second group of magnets 134 embedded in the second retaining ring 120. The first group of magnets 132 and the second group of magnets 134 have opposite poles facing each other, such that the first retaining ring 110 and second retaining ring 120 can be temporary and detachably mounted thereby securing a substrate in the substrate holder 100.

In some embodiments, the number of the first group of magnets 132 embedded in the first retaining ring 110 is equal to the number of the pins 140 of the first retaining ring 110, and the number of the second group of magnets 134 embedded in the second retaining ring 120 is equal to the number of the pins 140 of the second retaining ring 120. In some other embodiments, the number of the first group of magnets 132 embedded in the first retaining ring 110 is more or less than the number of the pins 140 of the first retaining ring 110, and the number of the second group of magnets 134 embedded in the second retaining ring 120 is more or less than the number of the pins 140 of the second retaining ring 120.

The substrate is clamped in the substrate holder 100 during transporting between different chambers and being processed in the chambers of the semiconductor manufacture processes. In some situations, the substrate needs to be flipped over along with the substrate holder 100. Therefore, it is important to prevent the substrate from being cracked, especially during transporting or flipping processes.

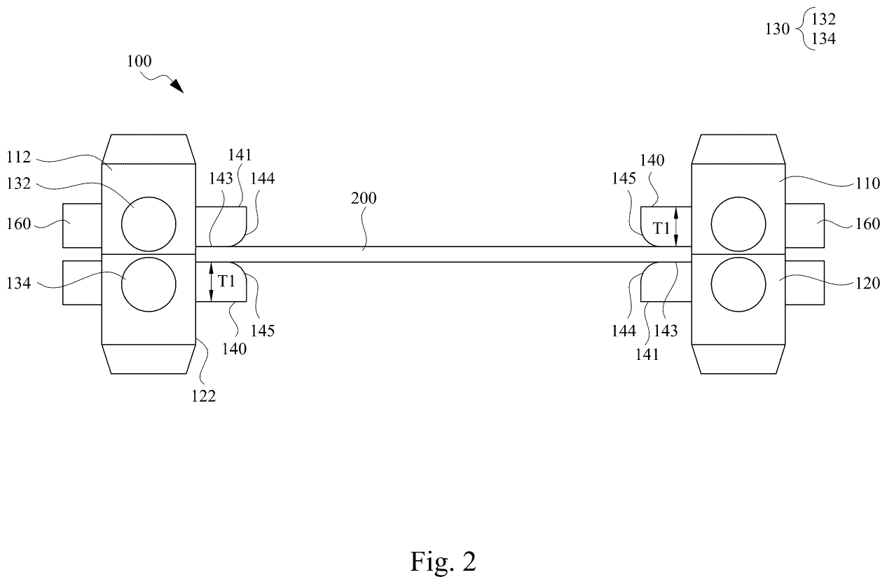

Reference is made to FIG. 2, which is a schematic cross-sectional view of the substrate holder with the substrate according to some embodiments of the disclosure. The substrate 200 is clamped in the substrate holder 100. More particularly, the substrate 200 is supported by the pins 140 when the substrate 200 is clamped in the substrate holder 100. The substrate holder 100 further includes two rotary shafts 160 connected to either one or both of the first and second retaining rings 110, 120, wherein the rotary shafts 160 are extended along a rotating axis of flipping the substrate 200.

The pins 140 are disposed on the inner circumferences 112, 122 of the first and second retaining rings 110, 120, instead of being disposed on the top or bottom surface of the first and second retaining rings 110, 120. The pins 140 are laterally extended from the inner circumferences 112, 122 of the first and second retaining rings 110, 120, and the distance between the pins 140 of the first and second retaining rings 110, 120 is substantially equals to the thickness of the substrate 200. The first and second retaining rings 110, 120 are in contact with each other when the substrate 200 is clamped in the substrate holder 100.

Each of the pins 140 has a top surface 141 and a bottom surface 143, in which the top surface 141 and the bottom surface 143 are planar surface. When the substrate 200 is clamped in the substrate holder 100, the substrate 200 is in contact with the bottom surfaces 143 of the pins 140 on the first retaining ring 110 and the top surfaces 141 of the pins 140 on the second retaining ring 120. Namely, the bottom surfaces 143 of the pins 140 on the first retaining ring 110 and the top surfaces 141 of the pins 140 on the second retaining ring 120 are the contact surfaces of the pins 140 against the substrate 200, and the contact surfaces of the pins 140 against the substrate 200 are planar surface. In some embodiments, a surface roughness of the contact surface of each of the pins is in a range from 50 μm to 300 μm.

In order to prevent the substrate from being cracked due to shifting or crushing during transporting or flipping processes, each of the pins 140 has a curved surface 144 at the distal end 145 of the pin 140. In some embodiments, the curved surface 144 of the each of the pins 140 is spaced from the substrate 200 to release the stress at the edge of the pins 140 and to avoid the sharp corner of the pins 140 scrubbing the substrate 200 when there is an unwanted shifting or crushing during transporting or flipping processes.

In some embodiments, the curved surface 144 is a curved corner at the distal end 145 of each of the pins 140, and the curved surfaces 144 of the pins 140 on the first retaining ring 110 and the curved surfaces 144 of the top surfaces 141 of the pins 140 on the second retaining ring 120 face each other. The shape and dimension of the curved surface 144 of each of the pins 140 is also considered. In some embodiments, the curved surface 144 of each of the pins 140 is a quarter circle in the cross-sectional view, and the curvature radius of the curved surface 144 of each of the pins 140 is equal to the thickness T1 of each of the pins 140, in which the thickness T1 is measured between the top surface 141 and the bottom surface 143 of the pin 140. In some embodiments, the thickness T1 of each of the pins 140 is in a range from 0.1 mm to 20 mm.

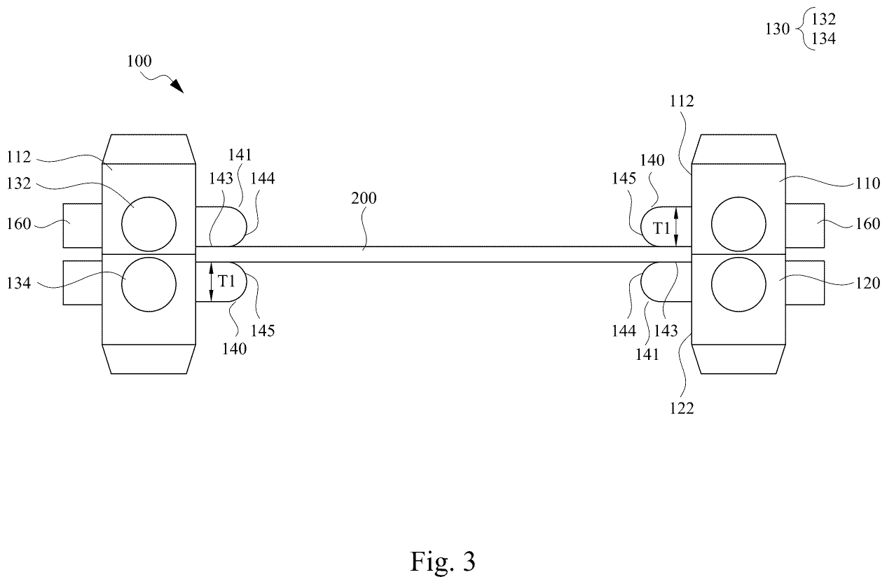

In some other embodiments, as shown in FIG. 3, which is a schematic cross-sectional view of the substrate holder with the substrate according to some other embodiments of the disclosure, the curved surface 144 is a side surface at the distal end 145 that interconnects the top surface 141 and the bottom surface 143 of each of the pins 140. In some embodiments, the curved surface 144 of each of the pins 140 is a half circle in the cross-sectional view, and the curvature radius of the curved surface 144 of each of the pins 140 is half the thickness T1 of each of the pins 140, in which the thickness T1 is measured between the top surface 141 and the bottom surface 143 of the pin 140. In some embodiments, the thickness T1 of each of the pins 140 is in a range from 0.1 mm to 20 mm.

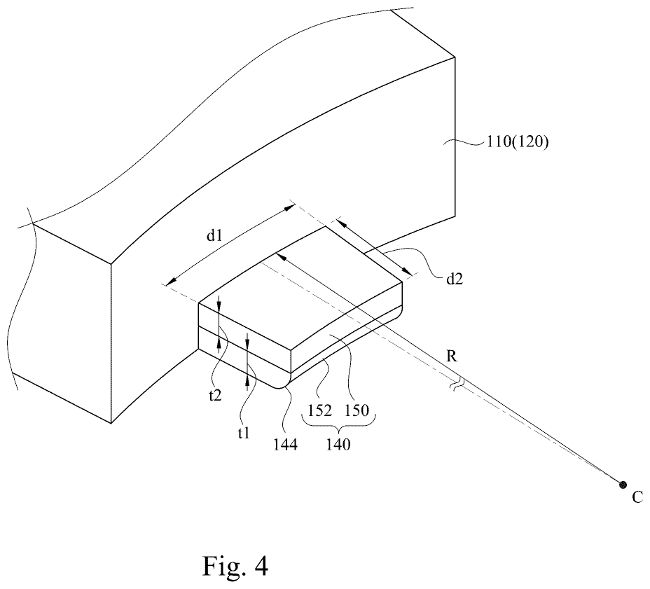

Reference is made to FIG. 4, which is partial oblique view of the substrate according to some embodiments of the disclosure. In some embodiments, the pin 140 includes a support piece 150 and a cushion 152 disposed on the support piece 150, and the cushion 152 has the curved surface 144. For example, the thickness t1 of the cushion 152 is in a range from 0.5 mm to 1 mm, the curved surface 144 of the pin 140 may be a quarter circle with a curvature radius equal to the thickness t1 of the cushion 152, in the cross-sectional view. Alternatively, similar to FIG. 3, the curved surface 144 of the pin 140 may be a half circle with a curvature radius of half of the thickness t1 of the cushion 152, in the cross-sectional view.

The Young's modulus of the cushion 152 is larger than the Young's modulus of support piece 150. The cushion 152 is made of more elastic material such as rubber or ceramic, and the support piece 150 is made of more rigid material such as stainless steel or aluminum.

In some embodiments, the pin 140 has a circumference dimension d1 measured at a circumference direction of the first or second retaining ring 110 or 120 and a radius dimension d2 at a radius direction that passes the center C of the first or second retaining ring 110 or 120. In some embodiments, the circumference dimension d1 of the pin 140 is in a range from 1 cm to 2 πR cm, in which R is the radius of the first or second retaining ring 110 or 120. In some embodiments, the radius dimension d2 of the pin 140 is in a range from 0.1 mm to 30 mm.

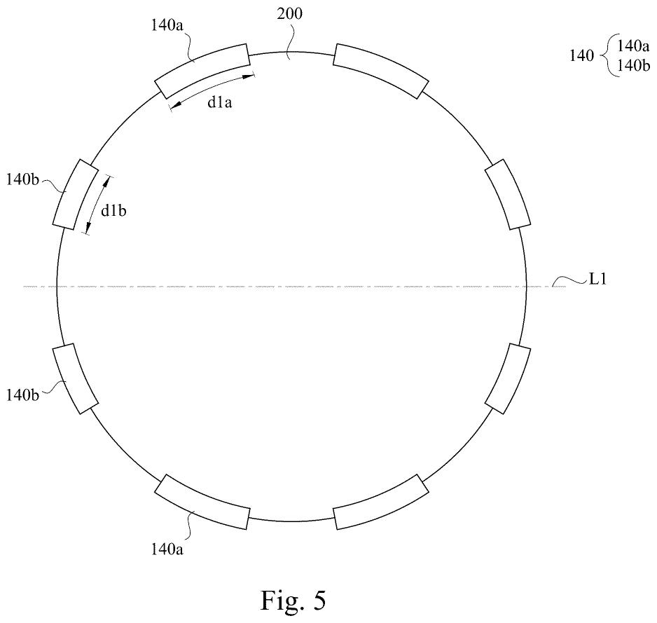

Reference is made to FIG. 5, which is a schematic top view of the arrangement of the pins according to some embodiments of the disclosure. The substrate 200 is flipped over along the rotating axis L1. It is observed that the force applied to the substrate holder 100 (as shown in FIG. 1) has a greatest amount near the rotating axis L1 when the substrate 200 is flipped over along with the substrate holder 100. Therefore, the arrangement of the pins 140 are also modified to prevent the substrate 200 from being cracked due to unwanted shifting or crushing.

In some embodiments, the pins 140 includes a first pin 140a and a second pin 140b, in which the second pin 140b is disposed closer to the rotating axis L1 than the first pin 140a, and the dimension of the first pin 140a is different from the dimension of the second pin 140b. In some embodiments, the circumference dimension d1a of the first pin 140a is greater than the circumference dimension d1b of the second pin 140b so that the contact area between the second pin 140b and the substrate 200 is smaller than the contact area between the first pin 140a and the substrate 200. By reducing the contact area between the pin 140 and the substrate 200 closer to the rotating axis L1, the risk of cracking during flip over process can be greatly reduced.

The pins 140 are symmetrically arranged along the rotating axis L1. In some embodiments, the pins 140 are O-shaped distributed on the inner circumference of each of the first and second retaining rings 110, 120 (as shown FIG. 1). The pins 140 are arranged evenly on the inner circumference of each of the first and second retaining rings 110, 120, with a constant spacing therebetween.

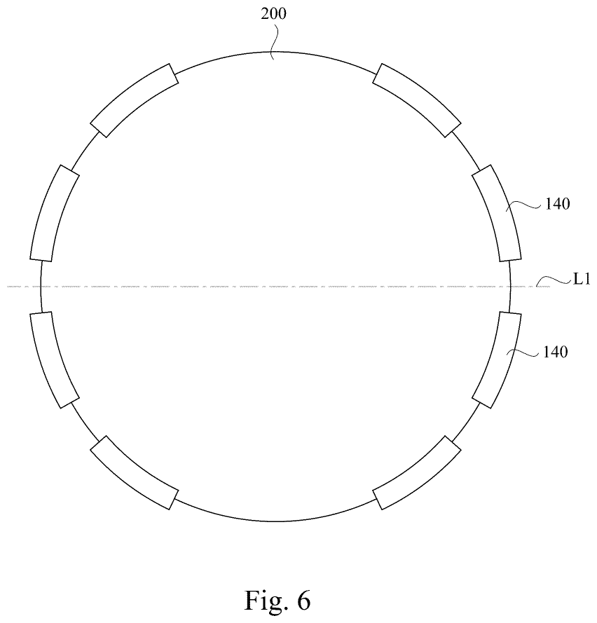

Reference is made to FIG. 6, which is a schematic top view of the arrangement of the pins according to some other embodiments of the disclosure. The pins 140 are symmetrically arranged along the rotating axis L1. In some embodiments, the pins 140 are C-shaped distributed on the inner circumference of each of the first and second retaining rings 110, 120 (as shown FIG. 1). The pins 140 are arranged on the inner circumference of each of the first and second retaining rings 110, 120 with varied spacing therebetween. For example, there is no pin 140 disposed on the inner circumference of each of the first and second retaining rings 110, 120, in the direction that is perpendicular to the rotating axis L1.

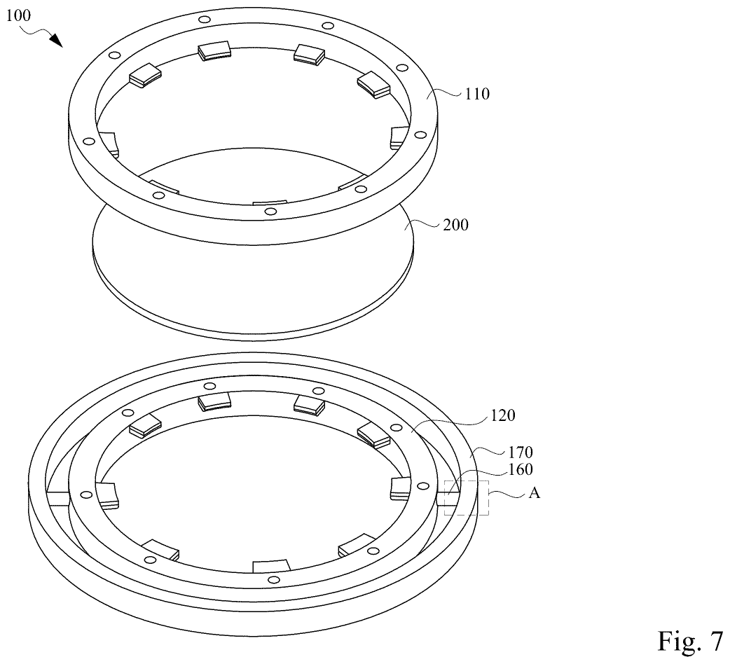

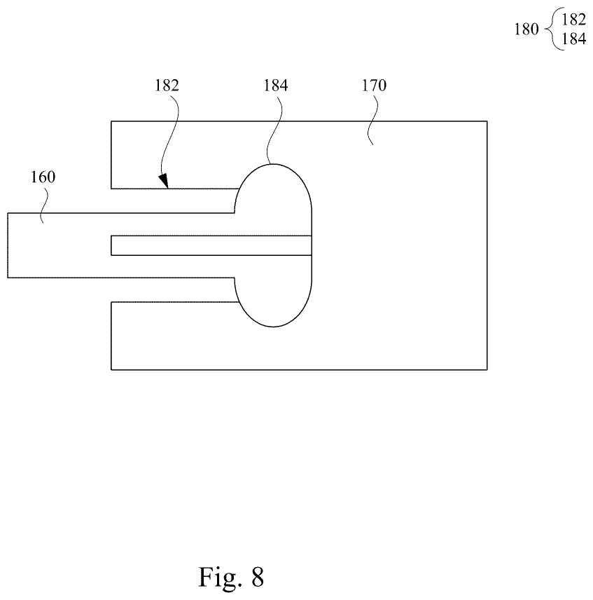

Reference is made to FIG. 7 and FIG. 8, in which FIG. 7 is an oblique view of the substrate holder according to some embodiments of the disclosure, and FIG. 8 is a schematic top view of region A of the substrate holder of FIG. 7. The substrate holder 100 further includes a support frame 170 connected to the second retaining ring 120 by the rotary shafts 160, wherein the second retaining ring 120 and the rotary shafts 160 are flippable relative to the support frame 170. The support frame 170 is configured to couple to a rotation holder of a rotation apparatus in a flipping station.

In some embodiments, the substrate holder 100 further includes two position mechanisms 180 configured to couple the rotary shafts 160 to the support frame 170, respectively. The position mechanisms 180 include slots 182 disposed in the support frame 170 and protrusions 184 disposed on the rotary shafts 160, respectively. The protrusions 184 of the rotary shafts 160 are contained in the slots 182 such that the second retaining ring 120 with the first retaining ring 110 and the substrate 200 can be maintained in a first position, e.g., the first retaining ring 110 on top, or in a second position, e.g., the second retaining ring 120 on top.

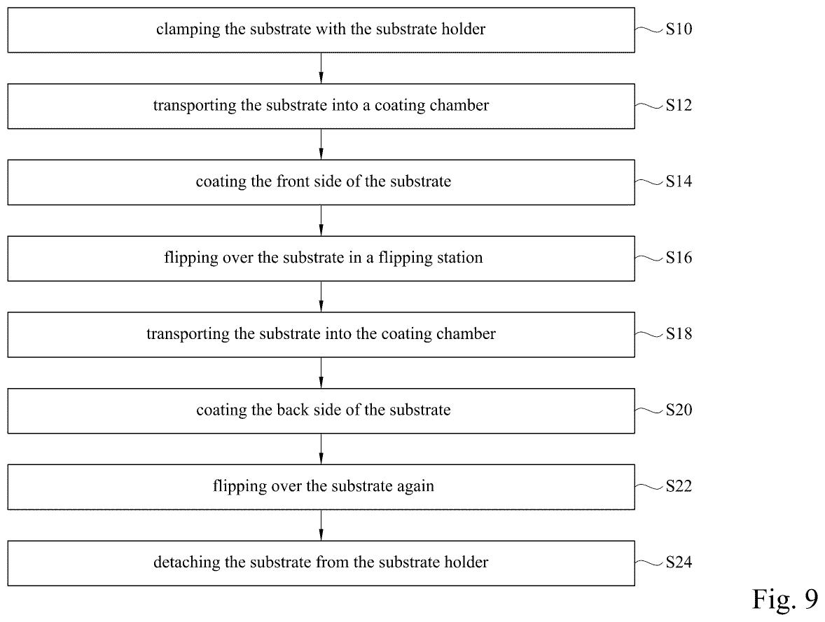

Reference is made to FIG. 9, which is a flow of a method of coating a substrate using the substrate holder according to some embodiments of the disclosure. In the method, step S10 includes clamping the substrate with the substrate holder such as the substrate holder 100 discussed in FIG. 1 to FIG. 7. The substrate is supported between the first and second retaining rings by the pins having the curved surfaces. Step S12 includes transporting the substrate along with the substrate holder into a coating chamber. In some embodiments, the substrate placed in the coating chamber is front side up, and the first retaining ring is on top. Step S14 includes coating the front side of the substrate, and the substrate is clamped in the substrate holder during the coating process.

After step S14 is completed, the substrate along with the substrate holder is transported to a flipping station in step S16. In some embodiments, the substrate holder is the substrate holder 100 of FIG. 1, and the entire substrate holder with the substrate is flipped over in the flipping station. Alternatively, in some other embodiments, the substrate holder is the substrate holder 100 of FIG. 7, the support frame is secured in the flipping station, and the first and second retaining rings along with the substrate are flipped over in the flipping station by rotating the rotary shafts. The substrate along with the substrate holder is flipped over in the flipping station, and the substrate is now back side up, and the second retaining ring is on top.

Step S18 includes transporting the substrate along with the substrate holder from the flipping station into the coating chamber again. Step S20 includes coating the back side of the substrate, and the substrate is clamped in the substrate holder during the coating process. After step S20 is completed, the substrate along with the substrate holder is transported to the flipping station in step S22, and the substrate is flipped over again in the flipping station. The substrate is back to front side up, and the first retaining ring is on top. Then, the method goes to step S24, including detaching the substrate from the substrate holder for the next semiconductor process.

In the method of coating the substrate using the substrate holder according to some embodiments of the disclosure, the substrate is clamped in the substrate holder during the transporting processes, coating processes, and flipping processes, there is no need to detach the substrate from the substrate holder, and the risk of substrate cracking and the time of loading/unloading the substrate can be reduced.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A substrate holder comprising:
a first retaining ring;
a second retaining ring;
a mounting component configured to detachably mount the first retaining ring on the second retaining ring; and
a plurality of pins disposed on an inner circumference of each of the first and second retaining rings, wherein each of the pins has a curved surface at a distal end of each of the pins.

2. The substrate holder of claim 1, wherein each of the pins comprises a support piece and a cushion disposed on the support piece, and the cushion of each of the pins has the curved surface.

3. The substrate holder of claim 2, wherein a thickness of the cushion of each of the pins is in a range from 0.5 mm to 1 mm.

4. The substrate holder of claim 1, wherein the curved surface of each of the pins is a curved corner at the distal end of each of the pins.

5. The substrate holder of claim 1, wherein the curved surface of each of the pins is a curved side surface that interconnects a top surface and a bottom surface of each of the pins.

6. The substrate holder of claim 1, wherein the curved surface is spaced from a substrate when the substrate is clamped in the substrate holder.

7. The substrate holder of claim 1, wherein a contact surface of each of the pins against a substrate is a planar surface.

8. The substrate holder of claim 1, wherein a surface roughness of each of the pins is in a range from 50 μm to 300 μm.

9. The substrate holder of claim 1, wherein the mounting component comprising a first group of magnets embedded in the first retaining ring and a second group of magnets embedded in the second retaining ring, and the first group of magnets and the second group of magnets have opposite poles facing each other.

10. The substrate holder of claim 9, wherein a number of the first group of magnets embedded in the first retaining ring is equal to a number of the pins of the first retaining ring.

11. The substrate holder of claim 1, wherein the pins are C-shaped distributed or O-shaped distributed on the inner circumference of each of the first and second retaining rings.

12. The substrate holder of claim 1, further comprising:
two rotary shafts connecting the first retaining ring, wherein the rotary shafts are extended along a rotating axis.

13. The substrate holder of claim 12, wherein the pins comprise a first pin and a second pin that is disposed closer to the rotating axis than the first pin, and a circumference dimension of the first pin is greater than a circumference dimension of the second pin.

14. The substrate holder of claim 12, wherein the pins are symmetrically arranged along the rotating axis.

15. The substrate holder of claim 12, further comprising:
a support frame connected to the second retaining ring by the rotary shafts, wherein the second retaining ring and the rotary shafts are flippable relative to the support frame.

16. The substrate holder of claim 15, wherein the support frame is configured to couple to a rotation holder of a rotation apparatus.

17. The substrate holder of claim 15, further comprising:
two position mechanisms configured to couple the rotary shafts to the support frame, respectively.

18. The substrate holder of claim 1, wherein each of the pins has a thickness in a range from 0.1 mm to 20 mm.

19. The substrate holder of claim 1, wherein each of the pins has a circumference dimension in a range from 1 cm to 2 πR cm, in which R is a radius of the first retaining ring.

20. The substrate holder of claim 1, wherein each of the pins has a radius dimension in a range from 0.1 mm to 30 mm.
